(19) United States
(12) Patent Application Publication
(10) Pub. No.: US 2010/0127239 A1
(43) Pub. Date: May 27, 2010

(54) III-Nitride Semiconductor Light Emitting Device

(75) Inventors: Eun Hyun Park, Seongnam-si (KR); Soo Kun Jeon, Seongnam-si (KR); Jae Gu Lim, Seongnam-si (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gumi-city (KR)

(21) Appl. No.: 12/648,589

(22) Filed: Dec. 29, 2009

Related U.S. Application Data
(63) Continuation of application No. PCT/KR2009/005091, filed on Sep. 10, 2009.

(30) Foreign Application Priority Data
Sep. 10, 2008 (KR) 10-2008-0089120

(51) Int. Cl. H01L 33/00

(52) U.S. Cl. 257/13; 257/14; 257/E33.008; 257/E33.023

(57) ABSTRACT

The present disclosure relates to a III-nitride semiconductor light-emitting device including an n-type nitride semiconductor layer, a p-type nitride semiconductor layer doped with a p-type dopant, an active layer disposed between the n-type nitride semiconductor layer and the p-type nitride semiconductor layer and including a quantum well layer to generate light by recombination of electrons and holes, and a diffusion barrier layer disposed between the quantum well layer and the p-type nitride semiconductor layer to be in contact with both layers, having a surface formed to make the interface with the p-type nitride semiconductor layer smooth, and to prevent diffusion of the p-type dopant into the quantum well layer.

### CROSS-REFERENCE TO RELATED APPLICATIONS

This application is a continuation of PCT Application No. PCT/KR2009/005091 filed on Sep. 10, 2009, which claims the benefit and priority to Korean Patent Application No. 10-2008-0089120, filed Sep. 10, 2008. The entire disclosures of the applications identified in this paragraph are incorporated herein by reference.

### FIELD

The present disclosure relates generally to a III-nitride semiconductor light-emitting device, and more particularly, to a III-nitride semiconductor light-emitting device which includes a diffusion barrier layer preventing Mg from being diffused into the last quantum well layer. The III-nitride semiconductor light-emitting device refers to a light-emitting device such as a light-emitting diode including a compound semiconductor layer composed of Al₍ₓ₎Ga_{(y)}In_{(1-x-y)}N (0≦x≦1, 0y≦1, 0≦x+y≦1), and may further include a material composed of other group elements, such as SiC, SiN, SiCN and CN, and a semiconductor layer made of such materials.

### BACKGROUND

This section provides background information related to the present disclosure which is not necessarily prior art.

FIG. 1 is a view of an example of a conventional III-nitride semiconductor light-emitting device. The III-nitride semiconductor light-emitting device includes a substrate 100, a buffer layer 200 grown on the substrate 100, an n-type nitride semiconductor layer 300 grown on the buffer layer 200, an active layer 400 grown on the n-type nitride semiconductor layer 300, a p-type nitride semiconductor layer 500 grown on the active layer 400, a p-side electrode 600 formed on the p-type nitride semiconductor layer 500, a p-side bonding pad 700 formed on the p-side electrode 600, and an n-side electrode 800 formed on the n-type nitride semiconductor layer exposed by mesa-etching the p-type nitride semiconductor layer 500 and the active layer 400.

In the case of the substrate 100, a GaN substrate can be used as a homo-substrate. A sapphire substrate, a SiC substrate or a Si substrate can be used as a hetero-substrate. However, any type of substrate that can have a nitride semiconductor layer grown thereon can be employed. In the case that the SiC substrate is used, the n-side electrode 800 can be formed on the surface of the SiC substrate.

The nitride semiconductor layers epitaxially grown on the substrate 100 are usually grown by metal organic chemical vapor deposition (MOCVD).

The buffer layer 200 serves to overcome differences in lattice constant and thermal expansion coefficient between the hetero-substrate 100 and the nitride semiconductor layers. U.S. Pat. No. 5,122,845 describes a technique of growing an AlN buffer layer with a thickness of 100 to 500 Å on a sapphire substrate at 380 to 800° C. In addition, U.S. Pat. No. 5,290,393 describes a technique of growing an Al₍ₓ₎Ga₍₁₋ₓ₎N (0x≦1) buffer layer with a thickness of 10 to 5000 Å on a sapphire substrate at 200 to 900° C. Moreover, PCT Publication No. WO/05/053042 describes a technique of growing a SiC buffer layer (seed layer) at 600 to 990° C., and growing an In₍ₓ₎Ga₍₁₋ₓ₎N (0<x≦1) thereon. In particular, there is provided with an undoped GaN layer with a thickness of 1 micron to several microns (μm) on the AlN buffer layer, the Al₍ₓ₎Ga₍₁₋ₓ₎N (0≦x<1) buffer layer or SiC/In₍ₓ₎Ga₍₁₋ₓ₎N (0<x≦1) layer.

In the n-type nitride semiconductor layer 300, at least the n-side electrode 800 formed region (n-type contact layer) is doped with a dopant. In some embodiments, the n-type contact layer is made of GaN and doped with Si. U.S. Pat. No. 5,733,796 describes a technique of doping an n-type contact layer at a target doping concentration by adjusting the mixture ratio of Si and other source materials.

The active layer 400 generates light quanta by recombination of electrons and holes. For example, the active layer 400 contains In₍ₓ₎Ga₍₁₋ₓ₎N (0<x≦1) and has a single layer or multi-quantum well layers.

The p-type nitride semiconductor layer 500 is doped with an appropriate dopant such as Mg, and has p-type conductivity by an activation process. U.S. Pat. No. 5,247,533 describes a technique of activating a p-type nitride semiconductor layer by electron beam irradiation. Moreover, U.S. Pat. No. 5,306,662 describes a technique of activating a p-type nitride semiconductor layer by annealing over 400° C. PCT Publication No. WO/05/022655 describes a technique of endowing a p-type nitride semiconductor layer with p-type conductivity without an activation process, by using ammonia and a hydrazine-based source material together as a nitrogen precursor for growing the p-type nitride semiconductor layer.

The p-side electrode 600 is provided to facilitate current supply to the p-type nitride semiconductor layer 500. U.S. Pat. No. 5,563,422 describes a technique associated with a light-transmitting electrode composed of Ni and Au and formed almost on the entire surface of the p-type nitride semiconductor layer 500, and in ohmic-contact with the p-type nitride semiconductor layer 500. In addition, U.S. Pat. No. 6,515,306 describes a technique of forming an n-type superlattice layer on a p-type nitride semiconductor layer, and forming a light-transmitting electrode made of indium tin oxide (ITO) thereon.

Meanwhile, the p-side electrode 600 can be formed thick not to transmit but to reflect light toward the substrate 100. This technique is called the flip chip technique. U.S. Pat. No. 6,194,743 describes a technique associated with an electrode structure including an Ag layer with a thickness over 20 nm, a diffusion barrier layer covering the Ag layer, and a bonding layer containing Au and Al, and covering the diffusion barrier layer.

The p-side bonding pad 700 and the n-side electrode 800 are provided for current supply and external wire bonding. U.S. Pat. No. 5,563,422 describes a technique of forming an n-side electrode with Ti and Al.

In the meantime, the n-type nitride semiconductor layer 300 or the p-type nitride semiconductor layer 500 can be constructed as a single layer or as plural layers. Vertical light-emitting devices are introduced by separating the substrate 100 from the nitride semiconductor layers using a laser technique or wet etching.

FIG. 2 is a graph of an example of a Mg doping profile of a p-type nitride semiconductor layer mentioned in PCT Publication No. WO/00/059046. The p-type nitride semiconductor layer 500 includes a p-type cladding layer 510 positioned adjacent to an active layer 400, a low-doped layer 520, and a p-type contact layer 530. The low-doped layer 520 is made of undoped GaN with a thickness of 2000 Å to improve an electrostatic discharge (ESD) characteristic. The p-type contact layer 530 is provided for contact with a p-side electrode 600 and made of GaN doped with Mg at a high concentration of 1×10²⁰/cm³ with a thickness of 1200 Å. Meanwhile, the p-type cladding layer 510 is made of AlGaN doped with Mg at a high concentration of 5×10¹⁹/cm³ with a thickness of 300 Å to drop a forward voltage of the light-emitting device and improve light efficiency. Here, although the low-doped layer 520 is not doped, since Mg is diffused from the p-type contact layer 530 and the p-type cladding layer 510 to the low-doped layer 520, the low-doped layer 520 has a doping concentration which is smaller than 1×10¹⁹/cm³ but still significant.

Accordingly, when the p-type cladding layer 510 is doped, it affects the undoped GaN layer provided to improve the ESD characteristic. The inventors of the present disclosure took an interest in the influences of the p-type impurity or p-type dopant (e.g., Mg) on the active layer 400, when it was doped on the p-type nitride semiconductor layer 500.

PCT Publication No. WO/07/004768 describes a method for controlling light emission of an active layer 400 including a plurality of quantum well layers. According to this method, light emission mostly occurs in the quantum well layers positioned adjacent to a p-type nitride semiconductor layer 500 among the plurality of quantum well layers.

### SUMMARY

This section provides a general summary of the disclosure, and is not a comprehensive disclosure of its full scope or all of its features.

There is provided herein a III-nitride semiconductor light-emitting device including: an n-type nitride semiconductor layer; a p-type nitride semiconductor layer doped with a p-type dopant; an active layer disposed between the n-type nitride semiconductor layer and the p-type nitride semiconductor layer and including a quantum well layer to generate light by recombination of electrons and holes; and a diffusion barrier layer positioned between the quantum well layer and the p-type nitride semiconductor layer to be in contact with both the layers, having a surface formed to make the interface with the p-type nitride semiconductor layer smooth, and to prevent diffusion of the p-type dopant into the quantum well layer. Here, the diffusion barrier layer refers to the last quantum barrier layer in relation to the active layer.

There is also provided herein a III-nitride semiconductor light-emitting device including: an n-type nitride semiconductor layer; a p-type nitride semiconductor layer doped with a p-type dopant; an active layer disposed between the n-type nitride semiconductor layer and the p-type nitride semiconductor layer and including a quantum well layer to generate light by recombination of electrons and holes; a diffusion barrier layer disposed between the quantum well layer and the p-type nitride semiconductor layer to be in contact with both the layers, having a surface formed using gallium, which is a group-III element, and indium, which is a surfactant increasing a surface migration distance of gallium, and preventing diffusion of the p-type dopant into the quantum well layer; and a quantum barrier layer disposed in the active layer on the opposite side to the diffusion barrier layer with respect to the quantum well layer and containing a smaller amount of indium than that of the diffusion barrier layer.

According to a III-nitride semiconductor light-emitting device of the present disclosure, the active layer can be protected from the p-type dopant (e.g., Mg) doped on the p-type nitride semiconductor layer, by having, for example, the structure for improving the ESD characteristic.

Also, according to a III-nitride semiconductor light-emitting device of the present disclosure, the last quantum well layer of the active layer can be protected from the high-doped p-type nitride semiconductor layer by improving the surface roughness of the last quantum barrier layer of the active layer.

Also, according to a III-nitride semiconductor light-emitting device of the present disclosure, the internal quantum efficiency of the III-nitride semiconductor light-emitting device can be improved by improving the structure of the last quantum barrier layer without changing the structure of the rest of the active layer.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a view of an example of a conventional III-nitride semiconductor light-emitting device.

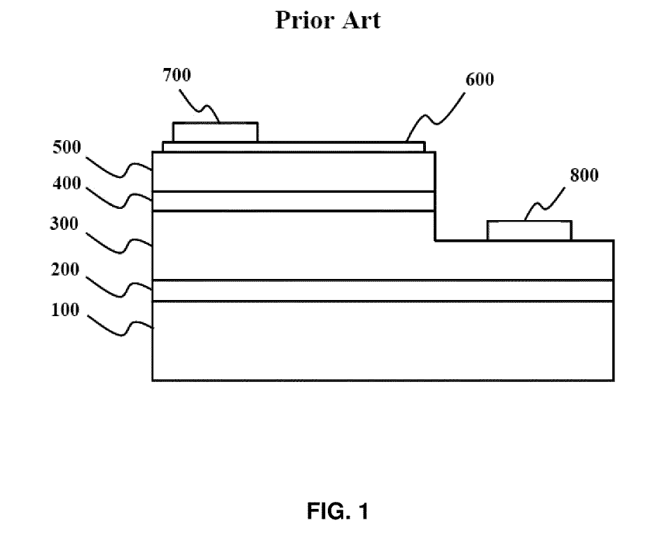

FIG. 2 is a graph of an example of a Mg-doping profile of a p-type nitride semiconductor layer mentioned in PCT Publication No. WO/00/059046.

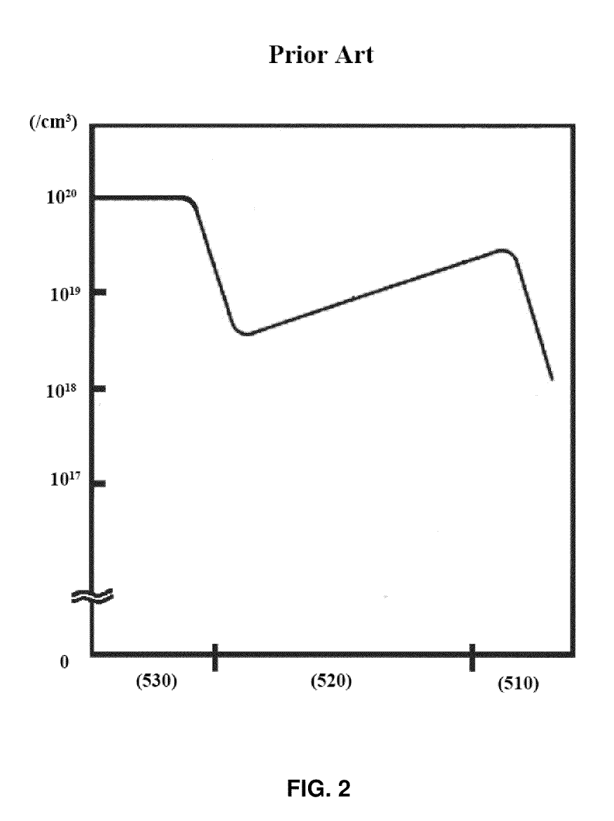

FIG. 3 is a view of an embodiment of a III-nitride semiconductor light-emitting device according to the present disclosure.

FIG. 4 is a view of one example of an active layer examined in the present disclosure.

FIG. 5 is an atomic force microscope (AFM) image of the last quantum barrier layer of the active layer shown in FIG. 4.

FIG. 6 is a scanning electron microscope (SEM) image of the active layer shown in FIG. 4.

FIG. 7 is a view of another example of the active layer examined in the present disclosure.

FIG. 8 is an AFM image of the last quantum barrier layer of the active layer shown in FIG. 7.

FIG. 9 is a graph of a Mg-doping profile measured by a secondary ion mass spectrometry (SIMS) system.

FIG. 10 is a graph of photoluminescence (PL) measurement results of light-emitting devices 1 and 2.

FIG. 11 is a graph of electroluminescence (EL) measurement results of the light-emitting devices 1 and 2.

FIG. 12 is a graph of the relationship between the mole fraction of In which is a surfactant, the surface roughness, and the density of V-shaped pits.

Corresponding reference numerals indicate corresponding parts throughout the several views of the drawings.

### DETAILED DESCRIPTION

Hereinafter, the present disclosure will now be described in detail with reference to the accompanying drawings.

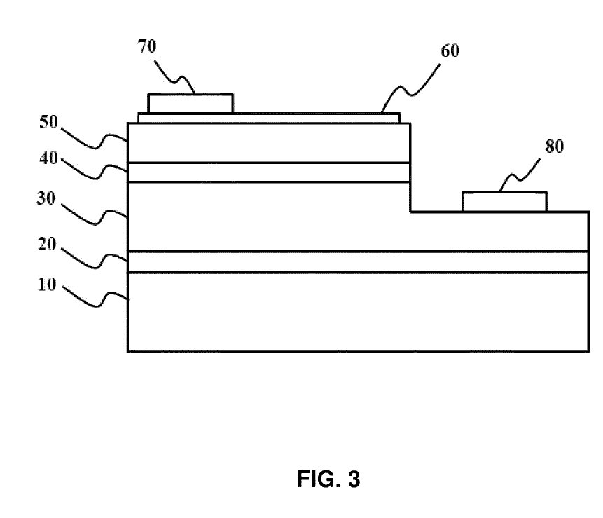

FIG. 3 is a view of an embodiment of a III-nitride semiconductor light-emitting device according to the present disclosure. The III-nitride semiconductor light-emitting device includes a substrate 10, a buffer layer 20 grown on the substrate 10, an n-type nitride semiconductor layer 30 grown on the buffer layer 20, an active layer 40 grown on the n-type nitride semiconductor layer 30, a p-type nitride semiconductor layer 50 grown on the active layer 40, a p-side electrode 60 formed on the p-type nitride semiconductor layer 50, a p-side bonding pad 70 formed on the p-side electrode 60, and an n-side electrode 80 formed on the n-type nitride semiconductor layer exposed by mesa-etching the p-type nitride semiconductor layer 50 and the active layer 40. The active layer 40 includes a plurality of quantum well layers and a plurality of quantum barrier layers.

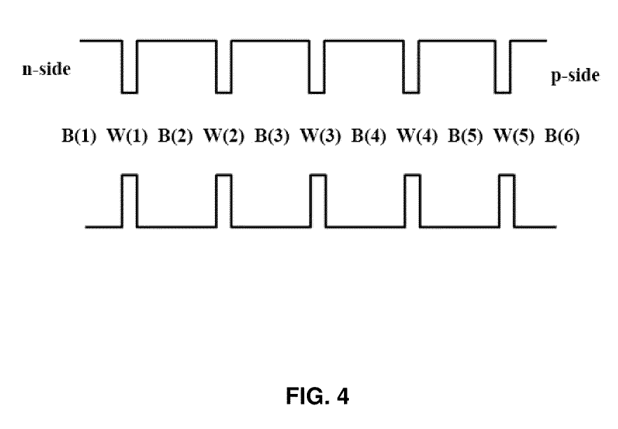

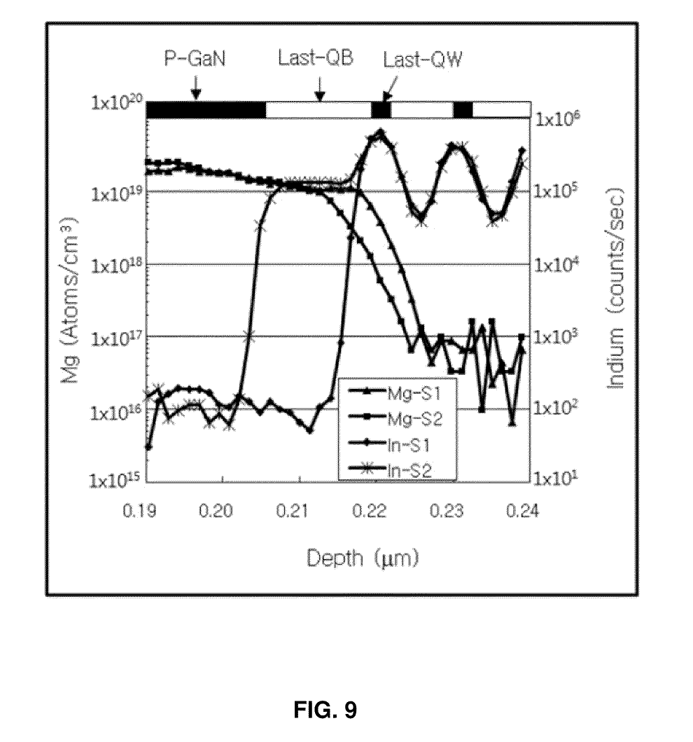

FIG. 4 is a view of one example of the active layer examined in the present disclosure. In the active layer 40, a plurality of quantum barrier layers B1, B2, B3, B4 and B5 made of GaN and a plurality of quantum well layers W1, W2, W3 and W4 made of InGaN are alternately stacked from the n-side, and the last quantum well layer W5 and the last quantum barrier layer B6 are positioned on the p-side. As illustrated in FIG. 9, the diffusion profile of Mg doped on the p-type nitride semiconductor layer 50 was observed with respect to the active layer 40 (referring to S1). When p-type GaN having a doping concentration of 2×10¹⁹/cm³ was used, the last quantum barrier layer B6 (last-QB) continuously maintained a doping concentration of 1×10¹⁹/cm³. Thus, the last quantum well layer W5 (last-QW) had a high doping concentration with an average of about 3×10¹⁸/cm³.

The inventors of the present disclosure examined surface images of the active layer 40 to study the diffusion mechanism of Mg proceeding from the p-type nitride semiconductor layer 50 to the last quantum well layer W5 via the last quantum barrier layer B6.

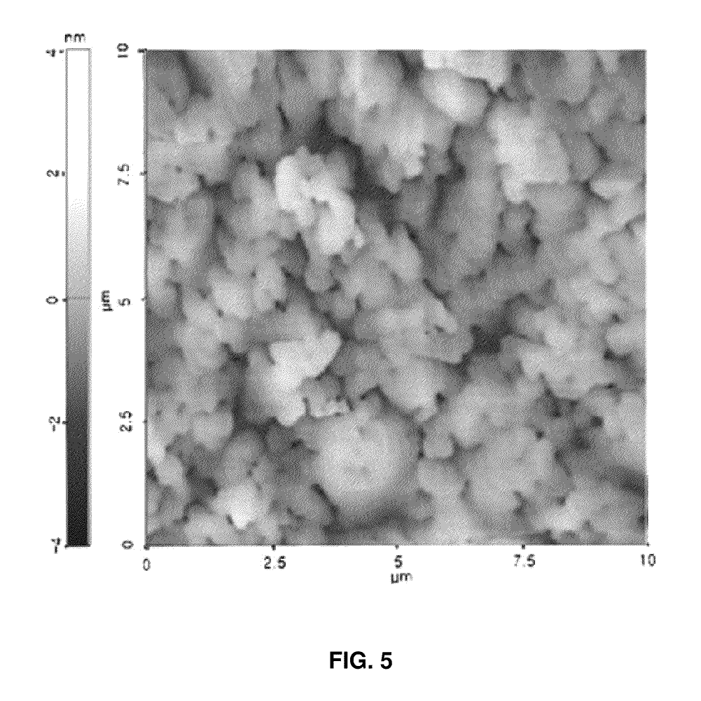

FIG. 5 is an AFM image of the last quantum barrier layer of the active layer shown in FIG. 4. A plurality of irregular grains made a very rough surface. To form a sample, a sapphire substrate was prepared as a substrate 10, a buffer layer 20 made of SiC/InGaN with a thickness of about 30 nm was formed on the substrate 10, an undoped GaN layer with a thickness of 2 μm was formed on the buffer layer 20, an n-type GaN layer doped with Si at 5×10¹⁸/cm³ and having a thickness of 2 μm was grown as an n-type nitride semiconductor layer 30, a plurality of quantum barrier layers B1, B2, B3, B4 and B5 made of GaN with a thickness of 100 Å, a plurality of quantum well layers W1, W2, W3 and W4 made of InGaN with a thickness of 30 Å were grown on the n-type nitride semiconductor layer 30 by five cycles, and the last quantum barrier layer B6 made of GaN was grown thereon. Here, the last quantum barrier layer B6 was grown at a speed of 0.5 Å/sec with a thickness of 15 nm under a pressure of 350 torr and a temperature of 850° C., using 200 sccm TEGa as a group-III source and 30 L ammonia as a group-V source.

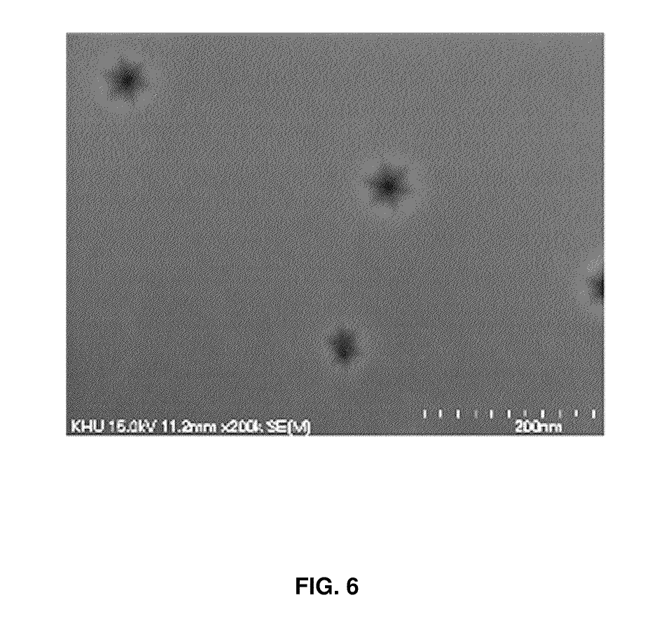

FIG. 6 is an SEM image of the active layer shown in FIG. 4. A plurality of V-shaped pits were formed on the surface of the active layer 40.

Based on this, the inventors of the present disclosure supposed that Mg was diffused into the last quantum well layer W5 through the interface between the rough surface and V-shaped pits of the last quantum barrier layer B6 and the p-type nitride semiconductor layer 50 and examined methods for preventing such diffusion in the last quantum barrier layer B6. Since the V-shaped pits originate from threading dislocation of thin films, it is difficult to control them in the last quantum barrier layer B6. Therefore, the inventors examined a method for improving surface roughness of the last quantum barrier layer B6. This can be achieved by increasing a migration distance of a Group-III element (e.g., Ga) on a growth surface during the growth of the thin film. According to this principle, when the migration distance of the group-III element increases on the growth surface, there is strong possibility that the group-III element is located in the surface energy-stable position, which reduces the surface roughness. Exemplary methods for increasing a surface migration distance of a group-III element include a method for reducing supply of a group-V element (e.g., N) to delay the coupling of a group-III element and the group-V element N, a method for reducing a growth speed of a thin film to secure time until the next layer is stacked to increase a migration distance of a group-III element, and/or a method for adding a surfactant increasing a surface migration distance of a group-III element.

Meanwhile, a barrier to Mg diffusion may be formed according to a method for increasing the thickness of the last quantum barrier layer B6, and may bring a side effect such as a high operating voltage of the light-emitting device. Accordingly, this method may be supplementarily considered with the present disclosure.

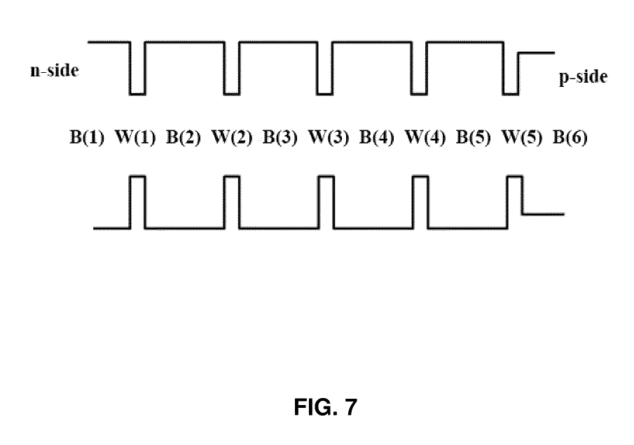

FIG. 7 is a view of another example of the active layer examined in the present disclosure. The last quantum barrier layer B6 has smaller bandgap energy than the other quantum barrier layers B1, B2, B3, B4 and B5. The active layer 40 was formed by using In as a surfactant, thereby increasing a surface migration distance of a group-III element and controlling the growth conditions. Here, the last quantum barrier layer B6 was grown at a speed of 0.5 Å/sec with a thickness of 15 nm under a pressure of 350 torr and a temperature of 850° C., using 200 sccm TEGa as a group-III source, 30 L ammonia as a group-V source, and 300 sccm TMIn as a surfactant. The In content of the last quantum barrier layer B6 grown was estimated to be about 3% by X ray and PL measurement.

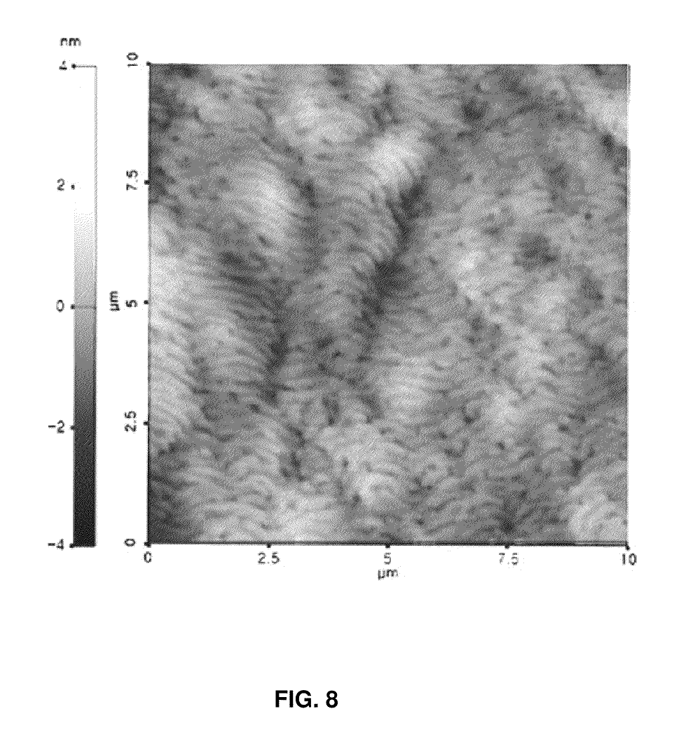

FIG. 8 is an AFM image of the last quantum barrier layer of the active layer shown in FIG. 7. It can be seen that roughness and morphology of the last quantum barrier layer B6 have been considerably improved.

The diffusion profile of Mg doped on the p-type nitride semiconductor layer 50 was examined with respect to the active layer 40 (refer to S2 of FIG. 9). Unlike the active layer 40 of FIG. 4, the last quantum barrier layer B6 (last-QB) had a doping concentration of 1×10¹⁹/cm³ to 1×10¹⁸/cm³, which meant that Mg diffusion was significantly prevented, and thus the last quantum well layer W5 (last-QW) had a doping concentration of about 5×10¹⁷/cm³.

Based on this, the inventors of the present disclosure fabricated two light-emitting devices to determine the influences of Mg exerted on the characteristic of the light-emitting device, when it was diffused into the last quantum well layer W5. The two light-emitting devices had the same structure as that of FIG. 3 except the active layer 40.

Light-emitting Device 1

A light-emitting device 1 was fabricated including an active layer 40 composed of five quantum well layers W1, W2, W3, W4 and W5 made of InGaN and six quantum barrier layers B1, B2, B3, B4, B5 and B6 made of GaN. The four quantum well layers W1, W2, W3 and W4 were designed to have a wavelength of 445 nm, and the last quantum well layer W5 was designed to have a wavelength of 475 nm so that it would be distinguished from them. Here, the wavelengths were controlled by adjusting the growth temperature.

Light-emitting Device 2

A light-emitting device 2 was fabricated in the same conditions as the light-emitting device 1 except the surface roughness of the last quantum barrier layer B6.

The light-emitting device 1 and the light-emitting device 2 were fabricated in the following conditions.

A C-plane sapphire substrate having a thickness of 420 μm was mounted in a metal-organic chemical vapor deposition (MOCVD) system as a substrate 10 and pre-baked at 1100° C. for 5 min. A buffer layer 20 made of SiC/InGaN with a thickness of 30 nm was grown at a reactor temperature of 550° C. Next, an undoped GaN layer having a thickness of 2 μm was grown at a reactor temperature of 1050° C., and an n-type GaN layer doped with Si at 5×10¹⁸/cm³ and having a thickness of 2 μm was grown as an n-type nitride semiconductor layer 30. After the reactor temperature was lowered to a level appropriate for an active layer 40, quantum barrier layers B1, B2, B3, B4 and B5 made of GaN with a thickness of 100 Å, and quantum well layers W1, W2, W3 and W4 (wavelength 445 nm, growth temperature 750° C.) and a quantum well layer W5 (wavelength 445 nm, growth temperature 730° C., made of InGaN, thickness of 30 Å) were sequentially grown in the N carrier atmosphere by five cycles. At this time, a difference between the growth temperatures of the quantum barrier layers B1, B2, B3, B4 and B5 and the quantum well layers W1, W2, W3, W4 and W5 was maintained at about 100° C.

Next, the last quantum barrier layer B6 made of GaN with a thickness of 150 Å was formed in the light-emitting device 1. Here, the last quantum barrier layer B6 was grown at a speed of 0.5 Å/sec with a thickness of 15 nm under a pressure of 350 torr and a temperature of 850° C., using 200 sccm TEGa as a group-III source, and 30 L ammonia as a group-V source.

Meanwhile, the last quantum barrier layer B6 made of In_{0.03}Ga_{0.97}N with a thickness of 150 Å was formed in the light-emitting device 2. Here, the last quantum barrier layer B6 was grown at a speed of 0.5 Å/sec with a thickness of 15 nm under a pressure of 350 torr and a temperature of 850° C., using 200 sccm TEGa as a group-III source, 30 L ammonia as a group-V source, and 300 sccm TMIn as a surfactant.

Next, a p-type GaN layer having a Mg-doping concentration of 2×10¹⁹/cm³ and a thickness of 150 nm was grown thereon at about 1000° C. as a p-type nitride semiconductor layer 50.

Finally, the light-emitting device 1 and the light-emitting device 2 were fabricated into chips of 600 μm×250 μm.

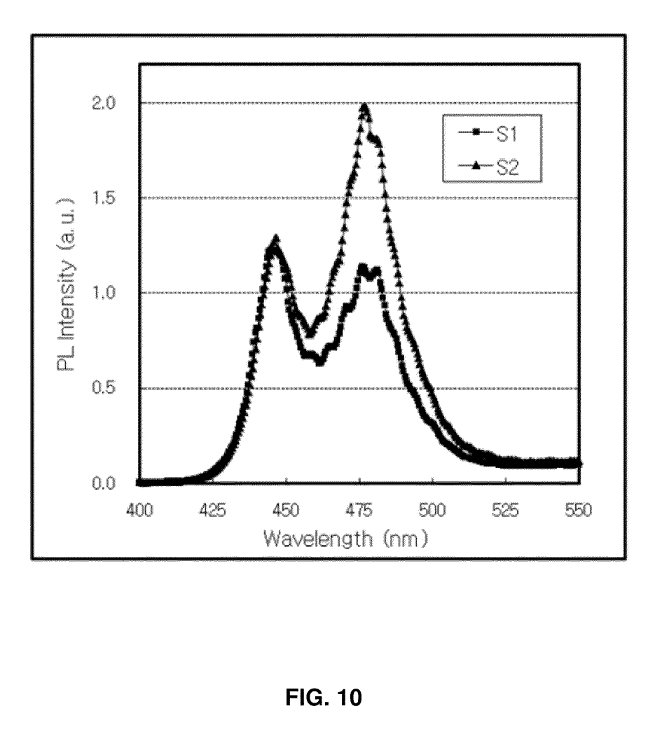

FIG. 10 is a graph of PL measurement results of the light-emitting devices 1 and 2. While the PL intensities of the light-emitting device 1 (referring to S1) and the light-emitting device 2 (referring to S2) were almost the same at 445 nm, the PL intensity of the light-emitting device 2 was improved at 475 nm by about 72%. As also seen from the SIMS results, the internal quantum efficiency of the quantum well layers W1, W2, W3 and W4, which were not affected by Mg, was the same in both light-emitting devices 1 and 2. On the contrary, according to the SIMS results, the internal quantum efficiency of the last quantum well layer W5 affected by Mg diffusion was significantly changed by the amount of the diffused Mg impurity.

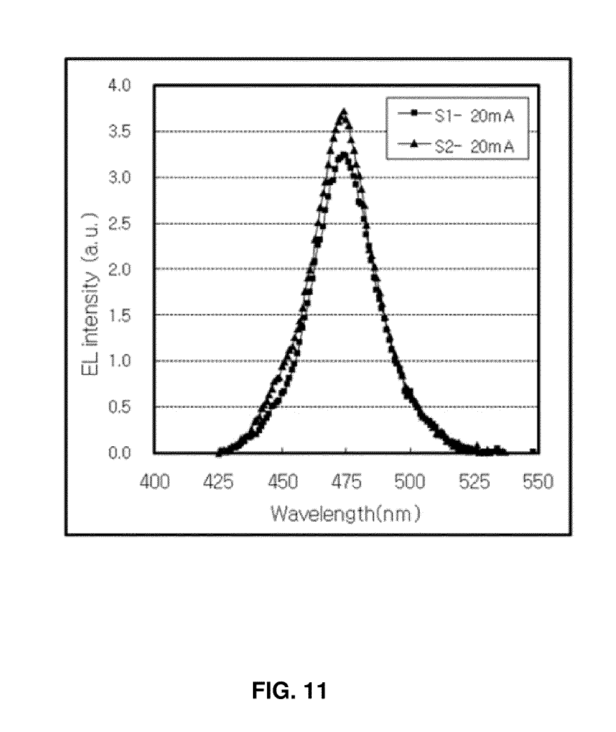

FIG. 11 is a graph of EL measurement results of the light-emitting devices 1 and 2. Light emission observed in the quantum well layers at 445 nm was relatively low because of a relatively large effective mass and low mobility of hole carriers. However, similar to the PL results, the EL intensity of the light-emitting device 2 (referring to S2) was less affected by the Mg impurity and was more improved at 475 nm than the EL intensity of the light-emitting device 1 (referring to S1) by about 15%. This means that Mg infiltrated into the last quantum well layer W5 had a considerable influence on the EL intensity.

It can be known from the PL and EL measurement results that the light-emitting device 2, including the last quantum well layer W5 subjected to less Mg diffusion, has an excellent light emission characteristic. Specifically, the interface between the active layer 40 and the p-type nitride semiconductor layer 50 can be made smooth by improving the surface roughness and/or morphology of the last quantum barrier layer B6, which prevents Mg diffusion. As a result, this improves the internal quantum efficiency of the active layer 40, including the last quantum well layer W5.

Hereinafter, various embodiments of the present disclosure will be described.

(1) The p-type nitride semiconductor layer 50 may include an undoped layer or a low-doped layer to improve the ESD characteristic. Here, the p-type nitride semiconductor layer 50 should further include a layer doped with Mg at a high concentration (e.g., 2×10¹⁹/cm³) so as to smoothly supply current to the active layer 40. Particularly, when the p-type nitride semiconductor layer 50 has the doping profile of the p-type dopant, the present disclosure is efficient to protect the active layer 40 from Mg diffusion.

(2) In terms of the doping profile of the p-type dopant (e.g., Mg) within a particular embodiment, when a section of the p-type nitride semiconductor layer 50 is brought into contact with the last quantum barrier layer B6 has a doping concentration equal to or greater than 1×10¹⁹/cm³, the average concentration in the last quantum well layer W5 is below 1×10¹⁸/cm³, i.e., 10¹⁷/cm ³, or lower.

In terms of the last quantum barrier layer B6, as illustrated in FIG. 9, the doping concentration sharply decreases from 1×10¹⁹/cm³ to 1×10¹⁸/cm³. However, regardless of the doping concentration of the p-type nitride semiconductor layer 50, the effect is significant if the doping concentration on the interface between the last quantum barrier layer B6 and the last quantum well layer W5 is reduced by at least 50% more than that on the interface between the last quantum barrier layer B6 and the p-type nitride semiconductor layer 50.

(3) In this disclosure, Mg is used as the p-type dopant. However, it is to be noted that the present disclosure is applicable to other p-type dopants such as Zn.

(4) To improve surface roughness of the last quantum barrier layer B6, In may be added as a surfactant increasing a surface migration distance of a group-III element. If In is excessively added, an energy barrier of the last quantum barrier layer B6 is lowered, which may result in low light emission efficiency of the light-emitting device.

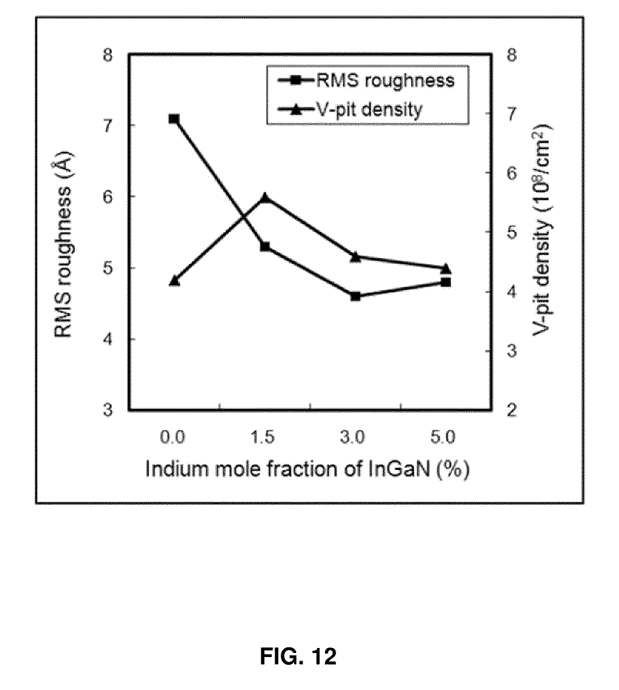

FIG. 12 is a graph of the relationship between the mole fraction of In which is a surfactant, the surface roughness, and the density of V-shaped pits, which shows changes in the surface roughness and the density of the V-shaped pits when In is added to improve roughness of the last quantum barrier layer B6 made of GaN. In-added GaN was represented by InₓGa₁₋ₓN. The surface roughness was improved from 7 Å to 6 Å by about 15% from the time when about 1% (x=0.01) In was added. The surface roughness was continuously improved as the content of In increased, reached the lowest value when it was about 3%, and slightly increased when it was about 5% (root mean square (RMS) roughness of the surface of 10×10 μm² was calculated). Accordingly, considering the surface planarization effect, the minimum value x of In serving as the surfactant is preferably equal to or greater than 0.01, and more preferably, equal to or greater than 0.02. When x was 0.03, the surface roughness was most improved. Therefore, in the present disclosure, x may be limited to values equal to or greater than 0.03.

(5) On the other hand, so far as the inventors of the present disclosure understand, when x is equal to or greater than 0.01 in a light-emitting device using a quantum barrier layer made of InₓGa₁₋ₓN (generally, all the quantum barrier layers have the same x value), an energy barrier becomes low, and thus the electron confinement worsens in a quantum well layer. In addition, as the content of In in the entire active layer increases, thin film quality of the active layer is degraded due to strain, so that efficiency of the light-emitting device is severely reduced. Thus, in this particular embodiment, when a plurality of quantum barrier layers made of InₓGa₁₋ₓN are used, only x of the last quantum barrier layer B6 can be set to be equal to or greater than 0.01; x of the other quantum barrier layers can be set to be less than 0.01.

That is, in this particular embodiment, x of the last quantum barrier layer B6 made of InₓGa₁₋ₓN may have a value equal to or greater than 0.01, which is greater than x of the other quantum barrier layers. Meanwhile, if x is excessively large, the energy barrier is excessively lowered, which offsets the effect of improving efficiency of the last quantum well layer by preventing Mg diffusion. Considering this, it is difficult to set x to be equal to or greater than 0.15.

(6) In order to prevent the energy barrier of the last quantum barrier layer B6 from being lowered, it is possible to add Al which can serve to raise the energy barrier.

(7) There are no special limitations on the maximum thickness of the last quantum barrier layer B6. However, if the last quantum barrier layer B6 is too thick, it assists in preventing Mg diffusion, but may serve as a resistance that increases an operating voltage of the light-emitting device and cause loss of holes having very low mobility (about 1/20 of electrons) and a very large effective mass (about 5 times of electrons). With respect to this, it would be very difficult to set the thickness of the last quantum barrier layer B6 to be equal to or larger than 1000 Å. The minimum thickness of the last quantum barrier layer B6 is preferably equal to or larger than 50 Å, which prevents Mg diffusion.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A III-nitride semiconductor light-emitting device, comprising:
an n-type nitride semiconductor layer;
a p-type nitride semiconductor layer doped with a p-type dopant;
an active layer positioned between the n-type nitride semiconductor layer and the p-type nitride semiconductor layer and including a quantum well layer to generate light by recombination of electrons and holes; and
a diffusion barrier layer disposed between the quantum well layer and the p-type nitride semiconductor layer to be in contact with both the layers, having a surface formed to make the interface with the p-type nitride semiconductor layer smooth, and to prevent diffusion of the p-type dopant into the quantum well layer.

2. The III-nitride semiconductor light-emitting device of claim 1, wherein the region of the p-type nitride semiconductor layer brought into contact with the diffusion barrier layer has a doping concentration equal to or greater than 1×10¹⁹/cm³.

3. The III-nitride semiconductor light-emitting device of claim 2, wherein the p-type nitride semiconductor layer further comprises a region having a doping concentration lower than that of the region brought into contact with the diffusion barrier layer.

4. The III-nitride semiconductor light-emitting device of claim 1, wherein the quantum well layer has an average doping concentration below 1×10¹⁸/cm³ with respect to the p-type dopant.

5. The III-nitride semiconductor light-emitting device of claim 4, wherein the region of the p-type nitride semiconductor layer brought into contact with the diffusion barrier layer has a doping concentration equal to or larger than 1×10¹⁹/cm³.

6. The III-nitride semiconductor light-emitting device of claim 1, wherein the diffusion barrier layer provides a doping concentration difference of at least 50% between the p-type nitride semiconductor layer and the quantum well layer.

7. The III-nitride semiconductor light-emitting device of claim 6, wherein the p-type dopant is magnesium.

8. The III-nitride semiconductor light-emitting device of claim 1, wherein the diffusion barrier layer comprises gallium and indium.

9. The III-nitride semiconductor light-emitting device of claim 8, wherein the diffusion barrier layer is made of InₓGa₁₋ₓN, wherein x is equal to or greater than 0.01.

10. The III-nitride semiconductor light-emitting device of claim 9, wherein the diffusion barrier layer is made of InₓGa₁₋ₓN, wherein x is equal to or greater than 0.02.

11. The III-nitride semiconductor light-emitting device of claim 10, wherein the diffusion barrier layer is made of InₓGa₁₋ₓN, wherein x is equal to or greater than 0.03.

12. The III-nitride semiconductor light-emitting device of claim 11, wherein the active layer comprises a quantum barrier layer disposed on the opposite side to the diffusion barrier layer with respect to the quantum well layer, and the quantum barrier layer comprises a smaller amount of indium than that of the diffusion barrier layer.

13. The III-nitride semiconductor light-emitting device of claim 12, wherein the diffusion barrier layer further comprises aluminum.

14. A III-nitride semiconductor light-emitting device, comprising:
an n-type nitride semiconductor layer;
a p-type nitride semiconductor layer doped with a p-type dopant;
an active layer positioned between the n-type nitride semiconductor layer and the p-type nitride semiconductor layer and including a quantum well layer to generate light by recombination of electrons and holes;
a diffusion barrier layer positioned between the quantum well layer and the p-type nitride semiconductor layer to be in contact with both the layers, having a surface formed using gallium and indium, and preventing diffusion of the p-type dopant into the quantum well layer; and
a quantum barrier layer disposed in the active layer on the opposite side to the diffusion barrier layer with respect to the quantum well layer and containing a smaller amount of indium than that of the diffusion barrier layer.
